(19) United States
(12) Patent Application Publication
(10) Pub. No.: US 2026/0282239 A1
(43) Pub. Date: Sep. 17, 2026

(54) FILMS, METHODS OF MAKING FILMS, AND DEVICES INCORPORATING THE FILM

(71) Applicant: University of Virginia Patent Foundation, Charlottesville, VA (US)

(72) Inventors: Mengtian Yin, Charlottesville, VA (US); Baoxing Xu, Charlottesville, VA (US)

(21) Appl. No.: 19/564,437

(22) Filed: Mar. 12, 2026

Related U.S. Application Data
(60) Provisional application No. 63/770,652, filed on Mar. 12, 2025.

(51) Int. Cl. H05K 3/20; H05K 1/09; H05K 1/18

(52) U.S. Cl. CPC H05K 3/207; H05K 1/095; H05K 1/18; H05K 2201/10098; H05K 2203/0537; H05K 2203/0545; H05K 2203/122

(57) ABSTRACT

The present disclosure is directed to membranes, films, method of making films and films, and devices including the films. In particular, the present disclosure is directed to methods of processing highly uniform soft thin films on liquid surfaces for flexible electronics, highly uniform soft thin films, and related systems thereof.

### CROSS-REFERENCE TO RELATED APPLICATIONS

This application claims the benefit of U.S. Provisional Application entitled “PROCESSING OF HIGHLY UNIFORM SOFT THIN FILMS ON LIQUID SURFACE FOR FLEXIBLE ELECTRONICS AND RELATED SYSTEMS THEREOF” and having Ser. No. 63/770,652, filed Mar. 12, 2025, which is herein incorporated by reference in its entirety.

### BACKGROUND

Flexible electronics can have a broad range of applications, including skin electronics, soft machines, and bio-integrated devices. Soft thin films that are capable of providing a platform for tailoring electronic components and/or conforming to a variety of surfaces and deformations without compromising functionality can be useful for fabrication of flexible electronics. However, current methods of fabricating these soft films often rely on solid substrates and experience problems with scalability, surface roughness, and pick-up difficulty. Further, the post-thermal annealing during polymerization or curing processes usually leads to residual stress in the films due to thermal mismatch between film and substrate, altering mechanical and physical properties of films for applications. Another challenge can be the subsequent pick-up of films from the substrates because of their strong adhesion, particularly for very thin films that can be easily deformed. In addition, the thickness uniformity of films often cannot be ensured on a large wafer substrate, which can limit the scalability of fabrication technologies.

### SUMMARY

The present disclosure is directed to membranes, films, method of making films and films, and devices including the films. In particular, the present disclosure provides for methods of processing highly uniform soft thin films on liquid surfaces for flexible electronics, highly uniform soft thin films, and related systems thereof.

In various aspects, a method of fabricating a film can include spreading a second liquid on a surface, spreading a first liquid on the second liquid, dispensing a first solution onto the first liquid to form a membrane, and curing the membrane to form the film. In some aspects, the first liquid can have a lower density than the second liquid. In further aspects, the first liquid can have a bottom area and a top area, where the top area of the second liquid boarders a bottom area of the first liquid, and where a top area of the first liquid boarders a gaseous environment. In some aspects, an equilibrium solubility of the second liquid in the first liquid and an equilibrium solubility of the first liquid in the second liquid can be less than or equal to about 1 percent weight. In various aspects, an equilibrium solubility of the first solution in the first liquid and an equilibrium solubility of the first liquid in the first solution can be less than or equal to about 1 percent weight. In further aspects, an equilibrium solubility of the first solution in the second liquid and an equilibrium solubility of the second liquid in the first solution can be less than or equal to about 1 percent weight.

Various aspects of the present disclosure also provide a film fabricated according to the methods described herein. In various aspects, a film can include one or more polymers, where the film can include a thickness of about 10 micrometers to about 200 micrometers, a statistical thickness variation across an area greater than or equal to about 1 square millimeter of the film can be no more than about 10% of an average thickness of the film, an average surface roughness of the film can be about 10 nanometers to about 1 micrometer, or a combination of any thereof.

### BRIEF DESCRIPTION OF THE DRAWINGS

Further aspects of the present disclosure will be more readily appreciated upon review of the detailed description of its various embodiments, described below, when taken in conjunction with the accompanying drawings.

FIGS. 1A-1E illustrate a fabrication and spreading mechanism of ink droplets on double-layer liquid substrates. FIG. 1A shows top-view optical images of a PEDOT:PSS ink droplet on a double-layer liquid substrate, showing two extreme controlled spreading behaviors: (top) non-spreading on PDMS-10% hexane/honey with σ₂/σ₁=2.168 and H/r=0.524 and (bottom) complete spreading on PDMS-1% hexane/honey with σ₂/σ₁=2.37 and H/r=0.612. Scale bars are 10 mm. FIG. 1B shows a schematic cross-sectional illustration of the theoretical model for an ink droplet spreading on a double-layer liquid substrate. r is the initial ink droplet radius, H is the thickness of the top layer liquid, R is the ink membrane radius at spreading equilibrium, σ_{d}, σₐ, σ₁ and σ₂ are the surface tensions of the ink, the air, top-layer liquid and bottom-layer liquid, respectively, and σ₂₁, σ_{d1}, σ_{d2}, σ_{da}, σ₁ₐ are the interfacial tensions between the ink, liquid 1, liquid 2, and air. FIG. 1C is a theoretical map predicting the spreading ratio of the ink droplet (R/r) at σ_{d}=σ₁. The indices (i), (ii), and (iii) represent experimental data (see material parameter in FIG. 24). FIG. 1D shows a 3D optical profilometer profile of PEDOT:PSS films fabricated with the non-spreading mechanism on PDMS-10% Hexane/honey liquid (top left) and directly printed on the silicon wafer substrates (top right), and the corresponding thickness variation profiles across the scanned area (bottom). Insets illustrate the microscopy images of the scanned areas. Scale bars: 1 mm. FIG. 1E shows 3D optical profilometer images of PEDOT:PSS films fabricated with the complete spread approach on PDMS-1% Hexane/honey liquid (top left) and directly printed on the silicon wafer substrates (top right) and the corresponding thickness variation profiles across the scanned area (bottom). Insets illustrate the microscopy images of the scanned areas. Scale bars: 1 mm.

FIGS. 2A-2D show a fabrication and feature characterization of continuous films, discrete patterns, and device layouts with the non-spreading and complete spreading approaches. FIG. 2A shows optical images of fabricated basic geometric shapes of PEDOT:PSS films with the non-spreading mechanism for (i) dots, (ii) lines, and (iii) curves (top) along with quantitative comparison of their dimensions to as-designs (bottom). FIG. 2B shows variations of printed solid circles with the controlled spread behavior of PEDOT:PSS droplet inks by tuning the thickness of the top-layer PDMS liquid (H): optical images (left) and measured radius compared to as-designs (right). Scale bar: 1 mm. Error bars are within the dots. FIG. 2C shows fabrication of complex geometric patterns with the different spreading control approaches. Non-spreading approach (i. RFID symbol and ii. Tree pattern), complete spreading approach (iii. Biohazard logo and iv. UVa logo), and their combined approach (v. Cavalier logo, vi. Taiji logo, vii. Minecraft pattern, and viii. Multiple-turn pattern. PEDOT:PSS droplet ink dyed with Silc Pig color pigments in pink and blue colors highlights the non-spreading and complete spreading regions, respectively. Insets show the as-designed patterns. Scale bar: 10 mm. FIG. 2D shows RFID structural layouts with scaled dimensions, 1:1 (original), 1:2 (half scale), and 1:3 (one-third scale), through the combination of non-spreading (highlight in blue box) and complete spreading (highlight in red box) approach, illustrating the fabrication scalability.

FIGS. 3A-3D show mechanical super-stretchability and deformation mechanism of printed PEDOT:PSS films. FIG. 3A shows variation in measured electrical resistance of the PEDOT:PSS films under a uniaxial mechanical stretching. The films printed on liquid was transferred onto a 100 μm-thickness PDMS film for testing while “on solid” refers to the films directly printed on the same 100 μm-thickness PDMS substrate using spin coating. FIG. 3B shows optical images of the 10 μm-thickness PEDOT:PSS films under different levels of stretch. FIG. 3C shows an evolution of surface morphology in the 10 μm-thickness PEDOT:PSS films under cyclic uniaxial stretch at a 15% strain (left), and variation in measured electrical resistance of the PEDOT:PSS films under a cyclic stretching at the strain of 15% (right). FIG. 3D shows schematic illustrations of deformation mechanism of PEDOT:PSS films in response to mechanical stretch. The conductive PEDOT phase denoted by particles are dispersed in the PSS matrix to form conductive percolation networks that indicate the overall conductance of the films and cracks by stretch. Scale bars: 10 mm.

FIGS. 4A-4F show performance characterization of the fabricated films and RFID devices on curved substrates. FIG. 4A shows optical images of the fabricated RFID layout after transfer onto a spherical substrate (i-iii) top and side views with highlights in the local contact between the RFID layout and the spherical substrate, and (iv) 3D profile at a local contact interface, (v) 2D and (vi) 3D local features at the spherical substrate and the backbone PDMS and PEDOT:PSS regions in the RFID layout highlighting the conformal contacts and seamless connections after transfer. FIG. 4B shows a comparison of electrical resistance (R) of the printed RFID layouts with various printing thickness before and after transfer onto flat substrates. FIG. 4C shows a normalized resistance change (AR/R) of the transferred RFID layout on spherical substrates with various curvatures (k) (top) in comparison with the commercial RFID tag at 865 MHz (bottom). FIG. 4D shows a measured return loss (S₁₁) over a swept frequency range for the fabricated RFID tag with the frequency 865 MHz chip implementation on a flat substrate (top), together with data from the commercial standard RFID tag (bottom). FIG. 4E shows a measured return loss (S₁₁) of the fabricated RFID with the frequency 865 MHz chip implementation on curved substrates with various curvature (k) (top) in comparison with the commercial RFID tag (bottom). Data points marked by “x” indicate undetectable signal. Insets show the image of the RFID tag on curved spherical substrates. FIG. 4F shows optical images of the fabricated RFID tags transferred on surfaces across one and two sharp corners and a tubular shape (left), and corresponding measured return loss (S₁₁) over a swept frequency range over a swept frequency range for the RFID tag with frequency chips of 865 MHz (right). Scale bars: 20 mm.

FIGS. 5A-5H show an application demonstration of printed RFID tags for food spoilage monitoring. FIG. 5A shows images of the fabricated five RFID tags (L #1-5) and a commercial RFID tag (L #1′) mounted on the surface of a plastic milk bottle (left) and image snapshots of milk poured into a glass cup showing color changes over a 10-day period (right). FIG. 5B shows plots of return loss (S₁₁) as a function of swept frequency for the fabricated RFID tag at the location L #1 and comparison with reference measurement on liquid water. FIG. 5C shows a graph summary depicting the variation in minimum return loss at the location L #1 over exposure days for the milk. FIG. 5D shows a comparison of minimum return loss measured from five RFID tags at different locations on the milk bottle at day 0. FIG. 5E shows images of the fabricated five RFID tags (L #1-5) and a commercial RFID tag (L #1′) mounted on the skin of a banana (left) and image snapshots of bananas exposed in air showing skin color changes from 0 to 10 days (right). FIG. 5F shows a recorded return loss (S₁₁) versus the swept frequency for the fabricated RFID tag mounted at the location L #1 on the banana at different days. FIG. 5G is a plot summary showing the variation in minimum return loss at the location L #1 as the banana is exposed over days. FIG. 5H shows a comparison of minimum return loss measured from five RFID tags at different locations on the banana at day 0.

FIG. 6 shows optimal images (top view) of a PDMS base polymer droplet on a dyed water surface demonstrating rapid spreading. Scale bar: 10 mm.

FIGS. 7A and 7B show a characterization of surface tension in (FIG. 7A) PEDOT:PSS ink solution with varying PEO and ethanol weight concentrations, and (FIG. 7B) PDMS-hexane solution with varying hexane weight concentrations.

FIG. 8 is a theoretical map showing how adjusting only the surface tension ratio between liquid 1 and the droplet ink (σ₁/σ_{d}) enables spread and non-spread behaviors. When σ₁/σ_{d}=1.3, a spread mechanism is achieved with R/r>1, regardless of the thickness of liquid 1.

FIGS. 9A and 9B show spreading behavior of ink droplets on liquid substrates. FIG. 9A shows top-view optical images of a PEDOT:PSS ink droplet on a double-layer liquid substrate, showing (iii) complete spreading on PDMS-1% hexane/honey with σ₂/σ₁=2.5 and H/r=0.786. These data are also used for comparison with theoretical predictions in FIG. 1C. Scale bars: 10 mm. FIG. 9B shows a comparison of the spreading ratios R/r over time for the droplet/double-layer liquid systems, highlighting the spreading and non-spreading behaviors. Scale bar: 10 mm.

FIGS. 10A and 10B show (FIG. 10A) optical images of fabricated solid quarter PEDOT:PSS circles with the non-spreading mechanism along with (FIG. 10B) comparison of their dimensions to as-designs.

FIGS. 11A and 11B show fabrication of typical geometric patterns (star, triangle, spiral, and meander) with the different spreading control approaches. FIG. 11A shows a non-spreading approach. FIG. 11B shows a complete spreading approach. The ink was PEDOT:PSS and the substrate was the PDMS-hexane/honey double-layer liquid system. Insets show the as-designed patterns. Scale bar: 10 mm.

FIGS. 12A and 12B show printing patterns with multiple inks, highlighting no material infusion at the joints with different approaches. FIG. 12A shows a non-spreading approach. FIG. 12B shows a complete spreading approach. The ink is PDMS (dyed for enhance contrast at joints) and the substrate is the hexane/honey double-layer liquid system. Scale bar: 10 mm.

FIG. 13 shows fabrication of RFID structural layouts with different geometric configurations and dimensions, (i) 928 MHz, (ii) 922 MHz, and (iii) 920 MHz, through the combination of non-spreading (highlight in red box) and spreading (highlight in blue box) approach.

FIGS. 14A and 14B show surface morphology of PEDOT:PSS films under various levels of stretching strain. “On liquid” refers to the film fabricated on liquid surface and was then transferred onto a 100 μm-thickness PDMS film for testing, while “on solid” refers to the films directly printed on the same 100 μm-thickness PDMS substrate. FIG. 14A shows a film with the thickness of 1 μm. FIG. 14B shows a film with the thickness of 60 μm. Scale bar: 10 mm.

FIGS. 15A and 15B show stretchability of the printed RFID layout. FIG. 15A is an optical image of the printed RFID layout with the thickness of 10 μm through the combination of non-spreading (highlight in blue box) and complete spreading (highlight in red box) approach. FIG. 15B shows variation in electrical resistance of the RFID layout under a uniaxial mechanical stretching. “On liquid” refers to the device fabricated on liquid surface and was then transferred onto a 100 μm-thickness PDMS film for testing, while “on solid” refers to the RFID layout directly printed on the same 100 μm-thickness PDMS substrate.

FIGS. 16A-16C show mechanical performance of the fabricated 10 μm PEDOT:PSS film pattern mounted on a curved substrate. FIG. 16A shows the “V” pattern of the printed PEDOT:PSS film (left) and a “V” shaped sticker (right) with the pattern transferred onto it. Dashed outline indicates the location of the transferred RFID tag behind the sticker. FIG. 16B shows the “V” pattern and sticker attached on a soft bottle surface. FIG. 16C shows resistance variation by dynamically changing the bottle's curvature via squeezing. R₀ denotes the initial resistance measured at the curvature of k=0 cm⁻¹.

FIGS. 17A and 17B show an RFID tag sensor and characterization setup. FIG. 17A shows an RFID image with the incorporation of IC chip (Alien Higgs-3). FIG. 17B shows an experimental setup illustration of RFID tag characterization.

FIG. 18 shows a measured return loss (S₁₁) over a swept frequency range for the fabricated RFID tags with three configurations (Patterns (i), (ii), and (iii), also see FIG. 13) and implementations of corresponding frequency chips of 928 MHz, 922 MHz, and 920 MHz on a flat substrate.

FIG. 19 shows plots of return loss (S₁₁) as a function of swept frequency for the commercial standard RFID tag at the location L #1′ for the milk.

FIGS. 20A and 20B show a signal from the printed RFID tags on monitoring milk. FIG. 20A is a graph summary depicting the variation in minimum return loss at the location L #2, L #3, L #4, L #5 over exposure days for the milk. FIG. 20B is a comparison of minimum return loss measured from five RFID tags at different locations on the milk bottle at day 1, 3, 7, and 10.

FIG. 21 shows a recorded return loss (S₁₁) versus the swept frequency for the commercial standard RFID tag mounted at the location #L1′ on the banana at different days.

FIGS. 22A and 22B show a signal from the printed RFID tags on monitoring banana. FIG. 22A is a plot summary showing the variation in minimum return loss at the location L #2, L #3, L #4, L #5 as the banana is exposed over days. FIG. 22B is a comparison of minimum return loss measured from five RFID tags at different locations on the banana at day 1, 3, 7, and 10.

FIG. 23 is a schematic cross-sectional illustration of the theoretical model for an ink droplet spreading on a double-layer liquid substrate. θ₁, θ₂ and γ₁ denote contact angles of the droplet on liquid 1. β₁, β₂ and γ₂ denote contact angles of the droplet at the interface between liquid 1 and liquid 2. σ_{d1}, σ_{da}, and σ₁ₐ represent the interfacial tensions between the droplet and liquid 1, the droplet and air, and the liquid 1 and air, respectively, and σ_{d2}, σ₂₁ are the interfacial tensions between the droplet and liquid 2, and the liquid 1 and liquid 2, respectively. σ_{d}, σ₁, and σ₂ represent surface tensions of the initial droplet, liquid 1, and liquid 2, respectively. R and R₂ are the contact radius of the droplet with the liquids 1 and 2, respectively. H is the thickness of the liquid 1.

FIG. 24 is a table of reagents used in producing FIG. 1C and FIGS. 9A and 9B to validate the developed theory. d, 1, and 2 represent the droplet, liquid 1, and liquid 2 respectively. σ₁ and σ₂ represent surface tensions of the liquid 1 and liquid 2.

### DETAILED DESCRIPTION

The present disclosure is directed to membranes, films, methods of making films and films, and devices including the films. In particular, the present disclosure is directed to methods of processing highly uniform soft thin films on liquid surfaces for flexible electronics, highly uniform soft thin films, and related systems thereof. Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, the preferred methods and materials are now described.

Before the present disclosure is described in greater detail, it is to be understood that this disclosure is not limited to particular embodiments described, and as such may, of course, vary. It is also to be understood that the terminology used herein is for the purpose of describing particular embodiments only, and is not intended to be limiting, since the scope of the present disclosure will be limited only by the appended claims.

As will be apparent to those of skill in the art upon reading this disclosure, each of the individual embodiments described and illustrated herein has discrete components and features which may be readily separated from or combined with the features of any of the other several embodiments without departing from the scope or spirit of the present disclosure. Any recited method can be carried out in the order of events recited or in any other order that is logically possible.

Where a range of values is provided, it is understood that each intervening value, to the tenth of the unit of the lower limit unless the context clearly dictates otherwise, between the upper and lower limit of that range and any other stated or intervening value in that stated range, is encompassed within the disclosure. The upper and lower limits of these smaller ranges may independently be included in the smaller ranges and are also encompassed within the disclosure, subject to any specifically excluded limit in the stated range. Where the stated range includes one or both of the limits, ranges excluding either or both of those included limits are also included in the disclosure.

It must be noted that, as used in the specification and the appended claims, the singular forms “a,” “an,” and “the” include plural referents unless the context clearly dictates otherwise. Thus, for example, reference to “a support” includes a plurality of supports. In this specification and in the claims that follow, reference will be made to a number of terms that shall be defined to have the following meanings unless a contrary intention is apparent.

As used herein, the following terms have the meanings ascribed to them unless specified otherwise. In this disclosure, “comprises,” “comprising,” “containing” and “having” and the like can have the meaning ascribed to them in U.S. patent law and can mean “includes,” “including,” and the like; “consisting essentially of” or “consists essentially” or the like, when applied to methods and compositions encompassed by the present disclosure refers to compositions like those disclosed herein, but which may contain additional structural groups, composition components or method steps (or analogs or derivatives thereof as discussed above). Such additional structural groups, composition components or method steps, etc., however, do not materially affect the basic and novel characteristic(s) of the compositions or methods, compared to those of the corresponding compositions or methods disclosed herein. “Consisting essentially of” or “consists essentially” or the like, when applied to methods and compositions encompassed by the present disclosure have the meaning ascribed in U.S. patent law, allowing for the presence of more than that which is recited so long as basic or novel characteristics of that which is recited is not changed by the presence of more than that which is recited, but excludes prior art embodiments.

### Definitions

In describing and claiming the disclosed subject matter, the following terminology will be used in accordance with the definitions set forth below.

Unless otherwise defined, all terms of art, notations and other scientific terminology used herein are intended to have the meanings commonly understood by those of skill in the art to which this disclosure pertains. In some cases, terms with commonly understood meanings are defined herein for clarity and/or for ready reference, and the inclusion of such definitions herein should not necessarily be construed to represent a substantial difference over what is generally understood in the art. The techniques and procedures described or referenced herein are generally well understood and commonly employed using conventional methodology by those skilled in the art.

As used herein, a “polymer” can refer to a substance composed of macromolecules formed by the chemical bonding of repeating structural units, or monomers. Macromolecules can be characterized by a high molecular weight (e.g., 10 to 10,000 Da) and can exhibit linear, branched, crosslinked, or networked architectures. A polymer can be naturally occurring (e.g., cellulose, proteins, gelatin, collagen, chitosan, silk fibroin, hyaluronic acid, DNA, etc.) or synthetically produced (e.g., polyethylene glycol (PEG), methocellulose, 1,3-diglycerolate, polyvinyl alcohol, an acrylate, a methacrylate, a norbornene, a thiol, a vinyl sulfone, a maleimide, etc.) and can be engineered to possess specific physical, chemical, mechanical, thermal, or biological properties. A polymer can be a thermoplastic polymer or a thermoset polymer. In an embodiment, the polymer can be a thermoset polymer such as a thermoset elastomer. In particular, the polymer can be a thermoplastic polymer such as a thermoplastic elastomer. In general, elastomers have both viscous and elastic properties (e.g., viscoelasticity) and have can be subjected to elastic deformation under stress and return to their original shape. A polymer can further be electroactive (e.g., electrically conductive) or non-electroactive. In various embodiments of the present disclosure, polymers can be used to fabricate films (e.g., highly uniform soft thin films).

As used herein, a “substrate” can refer to a base material or surface upon which processes, structures, or layers can be applied, built, or supported. A substrate can serve as a mechanical support or a functional surface and can be composed of a variety of materials including glass, silicon, metal, ceramic, plastic, or polymeric films. A substrate can provide a foundational layer upon which the films of the present disclosure can be applied according to various embodiments of the present disclosure. In various aspects of the present disclosure, a substrate can include objects (e.g., packaging, bottles, books, bags, etc.), produce (e.g., bananas, apples, peppers, tomatoes, etc.), adhesives (e.g., stickers, electrodes, skin adhesives, etc.) or other surface which the films of the present disclosure can be affixed to.

As used herein, a “film” can refer to a thin, flexible layer of material having a thickness substantially smaller than its length and width, typically ranging from nanometers to several hundred micrometers. The film can comprise one or more polymers that exhibit flexibility and/or stretchability. In an aspect, the film can further incorporate conductive pathways, fillers, additives, or patterned structures to impart desired electrical, optical, thermal, or barrier characteristics. In various aspects, the film can conform to non-planar surfaces and maintain structural integrity and electrical performance under mechanical deformation such as bending, stretching, folding, or twisting.

As used herein, “equilibrium solubility” can refer to a maximum amount of solute that dissolves in a solvent at a specific temperature and pressure, where the rates of dissolution and precipitation are equal. Equilibrium solubility can represent a saturated solution where the concentration of dissolved material remains constant. In some aspects, two liquids can be considered to be immiscible when an equilibrium solubility of a first liquid in a second liquid is less than or equal to about 1 percent weight and an equilibrium solubility of the second liquid in the first liquid is less than or equal to about 1 percent weight. Unless otherwise specified herein, an equilibrium solubility can refer to a maximum amount of solute that dissolves in a solvent at standard temperature and pressure.

As used herein, a “solution” can refer to a liquid mixture in which a minor component (a solute) is uniformly distributed within a major component (a solvent). In some aspects, a solution can include one or more polymers. In some aspects, a solution can include a polymeric ink solution (e.g., 1% PEDOT:PSS, 1.3% PEO).

As used herein, a “membrane” can refer to a liquid, gel, or un-crosslinked polymer film or coating that has been formed but not yet solidified or covalently bonded into a film. In various aspects, once the spreading of a solution on a liquid surface reaches equilibrium, a membrane is formed that can be cured at room temperature to form a film.

As used herein, a “design” can refer to a variety of geometric structures that can be formed by dispensing a solution on a liquid substrate. In some aspects, a design can include one or more dots, one or more straight lines, one or more curved lines, etc. that can form a variety of shapes. For example, a design can include an electrical circuit.

As used herein, a “frame” can refer to a structure used to confine a solution, ensuring that the fabricated patterns adhere closely to one or more designs. In various aspects, a frame can be a solid structure that is placed on top of a liquid surface to confine a solution dispensed onto the liquid surface. For example, a frame can include a PDMS structure formed in the shape of a design that floats on top of a liquid surface to confine spreading of a solution dispensed onto the liquid surface within the shape of the design.

Further definitions are provided in context below. Unless otherwise defined, all technical and scientific terms used herein have the same meaning as commonly understood by one of ordinary skill in the art. Although methods and materials similar or equivalent to those described herein can be used in the practice or testing of the present disclosure, suitable methods and materials are described herein.

### Discussion

The present disclosure is directed to membranes, films, methods of making films and films, and devices including the films. In particular, the present disclosure provides for methods of processing highly uniform soft thin films on liquid surfaces for flexible electronics, highly uniform soft thin films, and related systems thereof.

In various aspects, a method of fabricating a film can include spreading a second liquid on a surface, spreading a first liquid on the second liquid, dispensing a first solution onto the first liquid to form a membrane, and curing the membrane to form the film. In some aspects, the first liquid can have a lower density than the second liquid. In further aspects, the first liquid can have a bottom area and a top area, where the top area of the second liquid boarders a bottom area of the first liquid, and where a top area of the first liquid boarders a gaseous environment. In some aspects, an equilibrium solubility of the second liquid in the first liquid and an equilibrium solubility of the first liquid in the second liquid can be less than or equal to about 1 percent weight. In various aspects, an equilibrium solubility of the first solution in the first liquid and an equilibrium solubility of the first liquid in the first solution can be less than or equal to about 1 percent weight. In further aspects, an equilibrium solubility of the first solution in the second liquid and an equilibrium solubility of the second liquid in the first solution can be less than or equal to about 1 percent weight.

In some aspects, the method can further include transferring the film to a substrate. In further aspects, the first solution can include one or more polymers. In an aspect, at least one of the one or more polymers is a thermoplastic polymer (e.g., thermoplastic elastomer) or a thermoset polymer (e.g., thermoset elastomer). In various aspects, at least one of the one or more polymers can be electroactive. In some aspects, at least one of the one or more polymers can be non-electroactive.

In some aspects, the film can include a thickness of about 10 micrometers to about 200 micrometers. In further aspects, the film can include a thickness of about 15 micrometers to about 100 micrometers. In some aspects, the film can include a thickness of about 20 micrometers to about 50 micrometers. In various aspects, a statistical thickness variation across an area greater than or equal to about 1 square millimeter of the film can be no more than about 10% of an average thickness of the film. In some aspects, a statistical thickness variation across an area greater than or equal to about 1 square millimeter of the film can be no more than about 5% of an average thickness of the film. In further aspects, a statistical thickness variation across an area greater than or equal to about 1 square millimeter of the film can be no more than about 2% of an average thickness of the film. In various aspects, an average surface roughness of the film can be about 10 nanometers to about 1 micrometer. In some aspects, an average surface roughness of the film can be about 7 nanometers to about 5 micrometers. In further aspects, an average surface roughness of the film can be about 5 nanometers to about 10 micrometers.

In various aspects, dispensing the first solution can further include dispensing a plurality of drops of the first solution onto the first liquid based at least in part on a design to form the membrane, where the plurality of drops forms the design. In some aspects, the design can be an electrical circuit and the method further includes disposing a radio frequency identification (RFID) chip onto the film and in connection with the electrical circuit. In some aspects, dispensing the first solution can further include placing a frame on the first liquid, where the frame has a design, and dispensing a plurality of drops of the first solution within the frame onto the first liquid to form the membrane, where the plurality of drops forms the design. In some aspects, dispensing the first solution can further include dispensing the first solution onto the first liquid based at least in part on a spreading radius of the first solution, where the spreading radius is based at least in part on a thickness of the first liquid, a surface tension of the first liquid, or both. In various aspects, a ratio of a surface tension of the first liquid to a surface tension of the second liquid can be greater than about 0.5 and a difference between a density of the second liquid and a density of the first liquid can be greater than or equal to about 0.1 g/cm³.

In some aspects, the first liquid can be a water-based polar liquid and the second liquid can be a nonpolar liquid. In various aspects, the first liquid can include water, saline, glycerol-water, or a combination of any thereof and the second liquid can include one or more alkanes, one or more silicone oils, one or more fluorinated oils, or a combination of any thereof. In other aspects, the first liquid can be a polar organic liquid and the second liquid can be a nonpolar liquid. In some aspects, the first liquid can include DMSO, DMF, one or more short-chain alcohols, water, or a combination of any thereof and the second liquid can include one or more alkanes, one or more mineral oils, one or more oils, or a combination of any thereof.

Various aspects of the present disclosure also provide a film fabricated according to the methods described herein. In various aspects, a film can include one or more polymers, where the film can include a thickness of about 10 micrometers to about 200 micrometers, a statistical thickness variation across an area greater than or equal to about 1 square millimeter of the film can be no more than about 10% of an average thickness of the film, an average surface roughness of the film can be about 10 nanometers to about 1 micrometer, or a combination of any thereof. In some aspects, the film can include a thickness of about 10 micrometers to about 200 micrometers. In further aspects, the film can include a thickness of about 15 micrometers to about 100 micrometers. In some aspects, the film can include a thickness of about 20 micrometers to about 50 micrometers. In various aspects, a statistical thickness variation across an area greater than or equal to about 1 square millimeter of the film can be no more than about 10% of an average thickness of the film. In some aspects, a statistical thickness variation across an area greater than or equal to about 1 square millimeter of the film can be no more than about 5% of an average thickness of the film. In further aspects, a statistical thickness variation across an area greater than or equal to about 1 square millimeter of the film can be no more than about 2% of an average thickness of the film. In various aspects, an average surface roughness of the film can be about 10 nanometers to about 1 micrometer. In some aspects, an average surface roughness of the film can be about 7 nanometers to about 5 micrometers. In further aspects, an average surface roughness of the film can be about 5 nanometers to about 10 micrometers.

In some aspects, at least one of the one or more polymers can be a thermoplastic polymer (e.g., thermoplastic elastomer) or a thermoset polymer (e.g., thermoset elastomer). In some aspects, at least one of the one or more polymers can be electroactive. In further aspects, at least one of the one or more polymers can be non-electroactive. In some aspects, the film can include an electrical circuit formed by the one or more polymers and a radio frequency identification (RFID) chip in connection with the electrical circuit.

In some aspects, an electrical resistance of the film can exhibit a change of less than about 2% after a plurality of cycles with a stretching strain of up to about 15%. In some aspects, an electrical resistance of the film can exhibit a change of less than about 1% after a plurality of cycles with a stretching strain of up to about 10%. In further aspects, the film can include a strain sensor, an electromyography (EMG) sensor, or other sensor. In various aspects, the film can be configured to filter a gas (e.g., CO₂). Various aspects of the present disclosure also provide a substrate including one or more of the films described herein.

### Example 1

### Introduction

Flexible electronics has emerged as a rapidly expanding field for a broad range of applications in skin electronics, soft machines, and bio-integrated devices. One consideration in their fabrication is the development of soft thin films, which can provide an adaptable platform for tailoring electronic components while conforming to various surfaces and accommodating deformations without compromising performance. Organic polymers who possess both electrically conductive and mechanically flexible properties are naturally considered ideal material candidates for producing soft films. Manufacturing such classes of soft films with uniform thickness, defect-free structures and straightforward transfer capability has been pursued to meet diverse needs of flexible electronics. Techniques such as spin coating, deposition, and 3D printing, often combined with photolithography and/or external field stimuli tools, have shown great achievements over the past decades. However, most of these approaches rely heavily on solid substrates, which introduces challenges such as limited scalability, substrate surface roughness, and post-fabrication transfer difficulty. For example, spin coating involves spreading liquid solutions onto spinning solid substrates to achieve films with well-defined thickness. This fabrication ability is yet very sensitive to the substrate's surface properties such as roughness and wettability that usually require a careful prior selection and/or surface treatment. Moreover, the post-thermal annealing during polymerization or curing usually leads to residual stress due to thermal-mismatch between films and substrates, altering mechanical and physical characteristics of films. Another issue that still remains is the subsequent pick-up of films from substrates because of their strong adhesion, especially for very thin films that can be easily deformed, although various transfer strategies are developed to reduce the adhesion like sacrificial layers and/or external stimuli. Employing liquid as an intermediate substrate in fabrication offers a facial strategy to address these challenges. For example, assembly of nanomaterials, such as nanoparticles, nanowires and nanoflakes, at liquid-liquid interface has been developed to grow functional films and structures, and dynamic flow of liquid is also introduced to improve assembly process by aligning orientation of materials and component units.

These assembly techniques are, however, typically limited to forming monolayer structures because of strong constraint accommodation of nanomaterials and molecules to two liquid phases at their interface. The inherent fluidity of liquid offers unique atomically smooth surface with disordered molecular structures, allowing for film formation without leaving any substrate footprint. Besides, its interaction with films is dominated by weak Van der Waals forces, which not only facilitate formation of uniformly thick in-plane structures but also simplify the mechanical transfer of the films. Such unique properties provide a significant and promising opportunity to fabricate soft thin films on liquid surfaces in a broad spectrum of parameter control and programmable design space.

Various aspects of the present disclosure introduce a facile, low-cost printing strategy for fabricating polymeric soft thin films on a liquid surface. This approach is inspired by the natural spreading of ink solution droplet on an immiscible liquid surface and is fully explored in both experiment and theory by employing a double-layer liquid substrate that can control the spreading of ink droplet atop. Remarkable agreement between theoretical predictions and experimental measurements is obtained and confirms the feasibility of this approach for diverse geometric structures including points, straight and curved lines, and planes across various dimensions. Continuous structures of thin films and electronic devices of radio-frequency identification (RFID) tags with various patterns and local features are fabricated to demonstrate controllability and accuracy of this processing approach to both global and local features. The films and tags exhibit exceptional thickness uniformity, excellent mechanical flexibility and stretchability, and high fabrication scalability. They are also transferred onto curved substrates with different curvatures, and quantitative electrical and communication tests further confirm device robustness. Applications of RFID tags on monitoring spoilage of both liquid (milk) and solid (banana) foods are demonstrated. The consistent performance across different mounting positions of tags shows the practical success and unique advantages of this approach in fabricating flexible electronics that can conform to curved surfaces while maintaining robust data communication.

### Results

### Fabrication Concept and Mechanics Mechanism

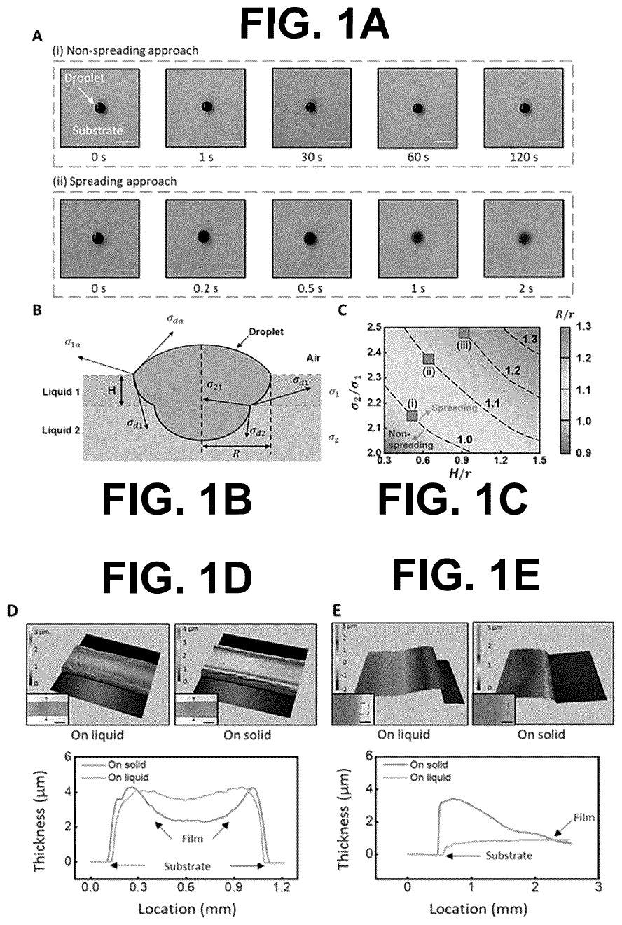

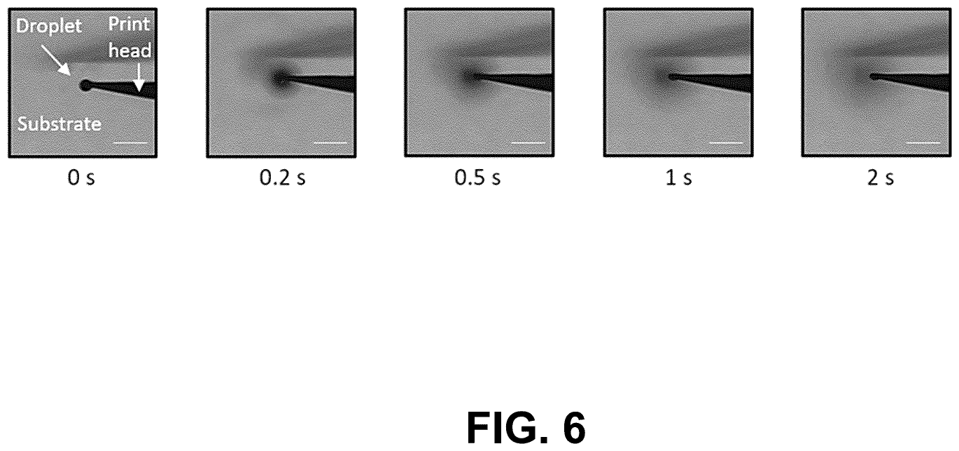

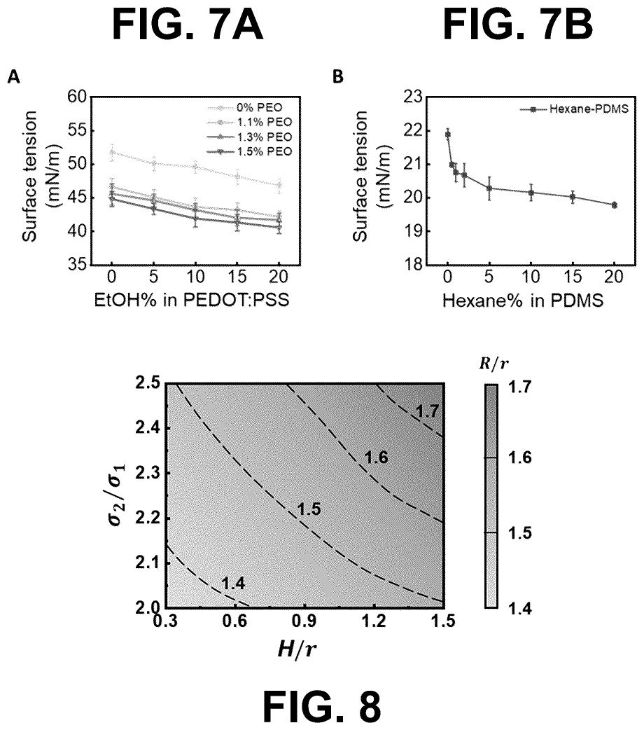

A droplet of polymeric ink solution usually spreads rapidly on a liquid surface when the surface tension difference induces a strong Marangoni flow, for example, polydimethylsiloxane (PDMS) base polymer quickly spreads on water (FIG. 6). To control this dynamic behavior, a double-layer liquid substrate is introduced. In this setup, a thin PDMS solution (PDMS base polymer-1% hexane) layer is fully spread over a bulk liquid substrate (honey) and forms a distinct immiscible liquid-liquid interface. Besides, its layer thickness is uniform after arrival of equilibrium due to the fluidic nature of PDMS solution. When a droplet of 1% poly(3,4-ethylenedioxythiophene)—polystyrene sulfonate (PEDOT:PSS) polymer solution comprised of 1.3% polyethylene oxide (PEO) and 10% ethanol (EtoH) is placed on the surface of this double-layer liquid substrate, its spreading can be precisely controlled by regulating the thickness and/or surface tension of the top PDMS layer solution. FIG. 1A shows experimental snapshots of two extreme controls. One is that the droplet of Ink_1 PEDOT:PSS solution (1% PEDOT:PSS, 1.3% PEO) retains its original size without spreading on PDMS-10% hexane/honey double layer liquid, while the other is that Ink_2 PEDOT:PSS solution (1% PEDOT:PSS, 1.3% PEO, 10% EtoH) spreads completely on PDMS-1% hexane/honey double layer liquid until reaching equilibrium. Surface tensions of the PEDOT:PSS ink solution with varying PEO and ethanol concentrations are characterized and summarized in FIGS. 7A and 7B. In theory, when an ink droplet with the printed radius of r is positioned on a double-layer liquid substrate, as illustrated in FIG. 1B (cross section view), its equilibrium spreading radius R depends on the thickness (H) of the top layer liquid and surface tension (σ₁) and can be determined in theory via (See Method section):

$$R ∝ r \frac{Φ ( \sqrt{{σ}_{2} / {σ}_{1}} - 1 ) + \frac{ρ {gHr}^{2}}{{σ}_{d} ( H + r )}}{( {σ}_{d} / {σ}_{1} )}$$

where σ_{d} is the surface tension of the ink droplet, σ₁ and σ₂ are the surface tensions of the top-layer and bottom-layer liquids, respectively, and p is the density of the ink. The dimensionless interaction parameter φ reflects the interfacial affinity between the two liquids of layer substrate. The term φ(\sqrt{σ₂/σ₁}−1) characterizes the energetic driving force for the droplet to penetrate through the top-layer liquid and contact the bottom-layer substrate-stronger preference, and larger σ₂/σ₁ leads to greater lateral spreading. The term

$$\frac{ρ {gHr}^{2}}{{σ}_{d} ( H + r )}$$

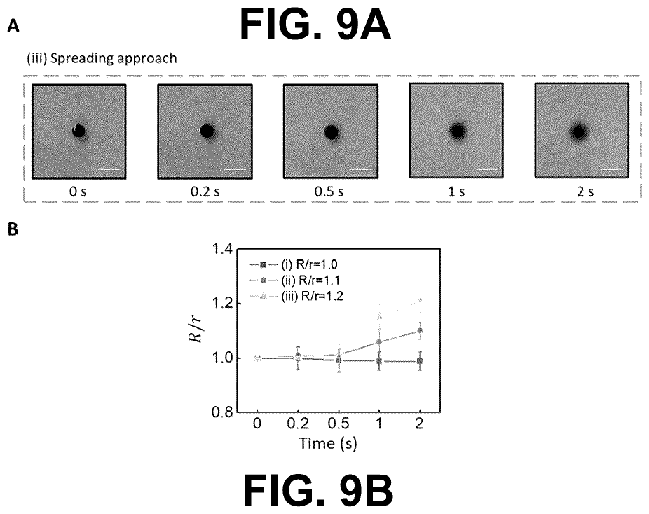

quantifies the geometric contribution from buoyancy, where thicker top-layer liquid enhances spreading by reducing downward penetration. The σ_{d}/σ₁ reflects the wettability contrast; when the droplet has lower surface tension relative to the top layer, it spreads more easily. FIG. 1C plots the theorical map of the spreading ratio (R/r) as a function of both material parameters and geometric dimensions. Smaller thickness H/r of top-layer liquid or larger surface tension of bottom layer liquid increases the spreading ratio (R/r). Higher surface tension ratios of the top-layer liquid to the bottom layer liquid (σ₂/σ₁) also enhances the spreading. When the surface tension ratio of the ink droplet to the top layer liquid changes, similar results are observed, as shown in FIG. 8. When the top-layer liquid is identical to the bottom bulk liquid, the double-layer liquid reduces to a single liquid substrate, and R/r>1 is obtained, following with that rapid spreading of droplet observed in FIG. 6. These theoretical predictions show agreement with experimental measurements (FIG. 1C and FIGS. 9A and 9B).

Once the spreading of the ink droplet on liquid surface reaches equilibrium, the resultant ink membrane is cured at room temperature to form a film. To assess the film's thickness uniformity and surface morphology, two extreme controllability to the droplet spreading were examined: non-spreading and complete spreading. For characterization, a PEDOT:PSS line formed on the PDMS-10% hexane/honey liquid substrate was transferred on a silicon substrate using the pull-up transfer method, where the PDMS-10% hexane/honey liquid substrate is completely drained and replaced by water (See Method section). For comparison, an identical ink droplet with same volume was directly printed on a silicon wafer substrate to form a line after cure at the room temperature. FIG. 1D shows a 3D optical profilometry image of the formed line with non-spreading. A highly uniform thickness and a very smooth surface are obtained. In contrast, a clear gradient with thicker edges across width is observed for the directly printed line on the silicon wafer substrate. When the PEDOT:PSS film is formed by the complete spreading control to the ink droplet on PDMS-1% hexane/honey liquid surface, FIG. 1E shows the 3D optical profilometry image after its transfer onto the silicon wafer. Compared to the film printed directly on the silicon substrate, the thickness is much more uniform across the entire spreading area on the liquid substrate. Quantitative thickness analysis of the formed lines (bottom panels of FIG. 1D and FIG. 1E) further confirms the super-uniformity of thickness in lines formed on the liquid surface with either non-spreading or complete spreading controls in comparison with those obtained on solid substrates.

### Diverse Structures and Scalability of Fabrication

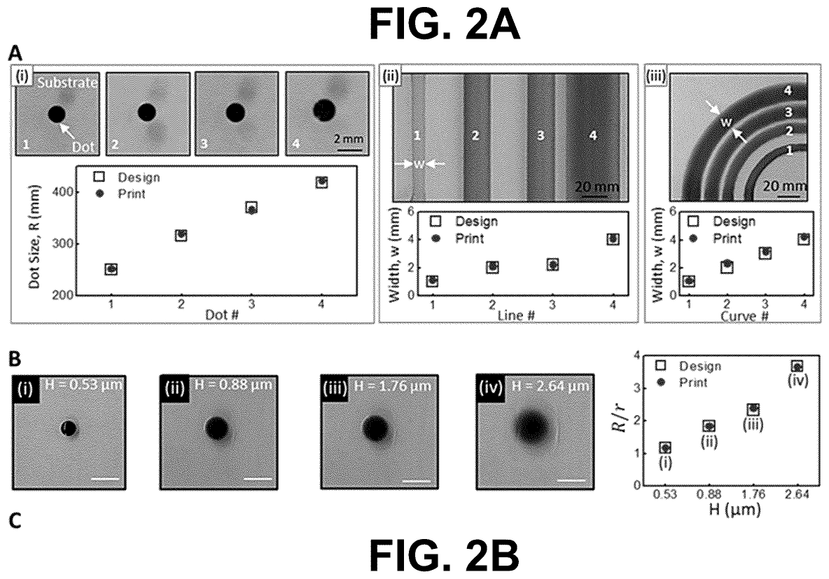

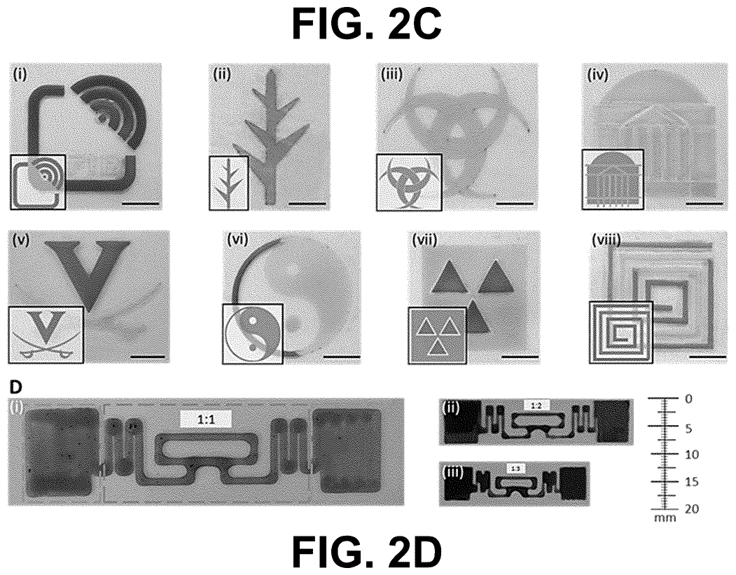

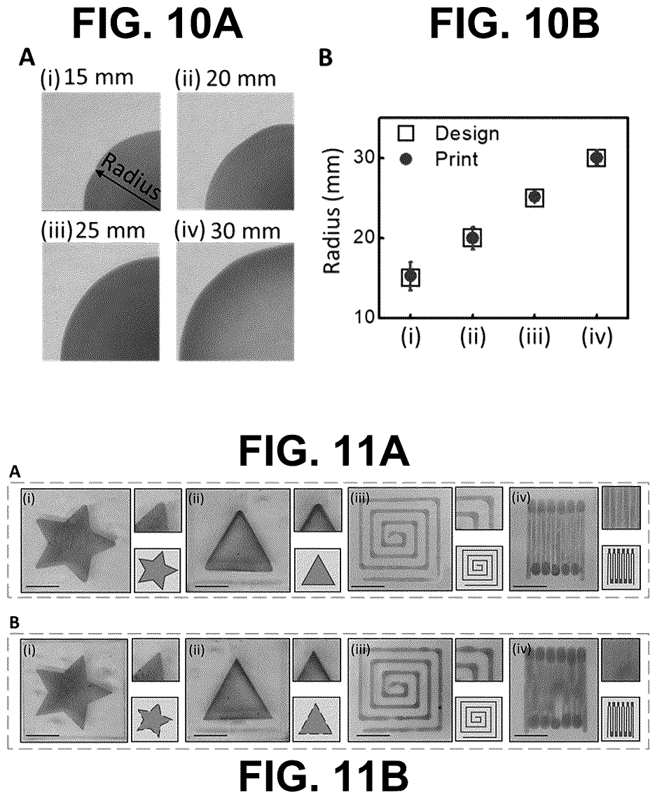

To further illustrate the controllability of this approach, PEDOT:PSS ink droplets were printed on PDMS-10% hexane/honey liquid substrate to form basic geometric structures. FIG. 2A shows optical images of dots, straight lines, and curved lines with different sizes produced through the non-spreading mechanism. Both the dots and lines are well printed in remarkable agreement with as-designs. Particularly, smooth edges in straight and curvilinear lines indicate the controlled spreading of the ink droplet. Similar results are observed for the fabricated circular shapes with different diameters (FIGS. 10A and 10B). Guided by the theoretical analysis (FIG. 1B and FIG. 8), films were further fabricated with a series of dimensions by modulating the spreading of ink solution through the thickness adjustment of top-layer PDMS-1% hexane liquid. FIG. 2B shows the optical images of the cured patterns after the complete spreading of ink droplets at room temperature, along with quantitative data comparison to as-designs. The consistency between the printed films and as-designs further confirms the excellent controllability of the ink droplet spreading processes.

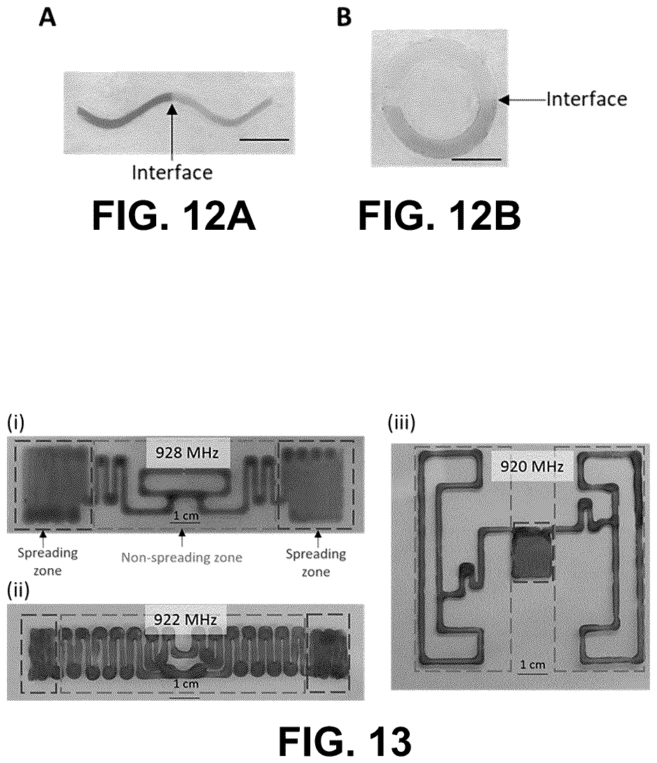

With the elucidation of spreading control for basic geometric units, diverse sets of films and structural patterns were fabricated using these two straightforward strategies of spreading and non-spreading control mechanisms. In FIG. 2C, i and ii present an RFID symbol and a tree symbol (dyed with Silc Pig blue color pigments in inks) respectively both fabricated using the non-spreading approach. Biohazard logo in iii and UVa logo in iv (dyed with Silc Pig pink color pigments in inks) are formed with the spreading control approach, where a PDMS film frame is used to confine the ink, ensuring that the fabricated patterns adhere closely to the as designs. Patterns with discrete elements (v and vi) can also be fabricated with the non-spreading control approach, where a backbone of PDMS is printed to maintain the designed spacings between element units on liquid surface. These patterns match very well with as-designs, indicating both the robustness of these fabrication mechanisms and the feasibility of liquid-based processing. Similar results are obtained for standard geometric patterns including star, triangle, spiral, and meander of PEDOT:PSS films formed on the PDMS-hexane/honey liquid surface, whether with the non-spreading or complete spreading mechanisms (FIGS. 11A and 11B). Further, the two control approaches can be combined to fabricate patterns of films by regulating the sequences and placement of droplets on the liquid surface, as shown in FIG. 2C, vii and viii, where the blue and pink colors highlight the corresponding non-spreading and complete spreading control regions. Particularly, when two different inks and/or control approaches are used, no material infusion at the joints of patterns is observed. This non-infusion does not occur at a large joint area regardless of geometric shapes and spreading control approaches, as further shown in FIG. 2C viii and FIGS. 12A and 12B, suggesting the potential for fabricating layered structures and multi-ink patterns. RFID patterns were also fabricated with different dimensions and layouts using spreading and non-spreading control. FIG. 2D gives optical images of RFID layouts with ALN-9662 shaped configuration. The high fidelity of these shaped layouts at a scaled-down size clearly demonstrates the scalability of this spreading and non-spreading control approach. Similar findings for RFID with other layouts are observed in FIG. 13. Although in both control approaches, patterns of film can be obtained and show good consistency in as-designs, achieving fine structural features down to the nanoscale may be challenging with the spreading mechanism approach due to promoted capillary effects in the constraint frames. In contrast, the non-spreading control approach offers better scalability, and fine patterns could be achieved by simply adjusting the ink droplet size.

### Performance Characterization, Deformation Mechanism, and Super-Flexible RFID Devices

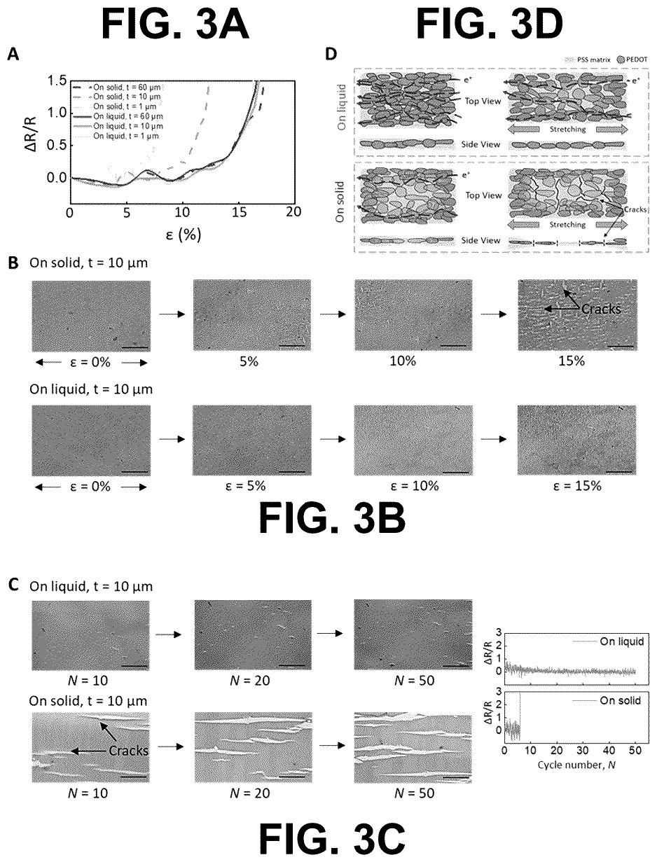

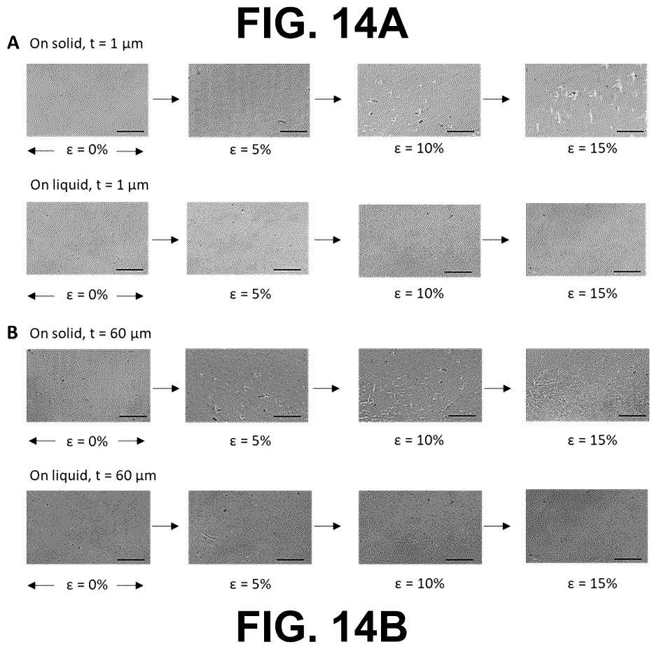

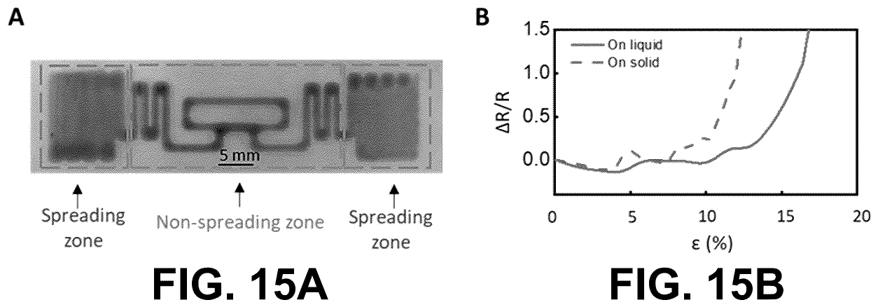

To assess the electrical conductance integrity of the PEDOT:PSS film formed on the PDMS-1% hexane/honey liquid surface, it is transferred onto a 100 μm-thick flat PDMS substrate, similar to that for the characterization in FIG. 1D and FIG. 1E. For comparison, the PEDOT:PSS films of the same thickness are also fabricated directly on the same 100 μm-thick flat PDMS substrate using spin coating (See Method section). FIG. 3A plots the variation of electrical resistance in response to a uniaxial stretch. For the films formed on the liquid surface, electrical resistance remains nearly constant up to about 15% strain, after which it rapidly increases as the film cracks. Besides, this behavior is largely independent of the film thickness. In contrast, the spin coated film exhibits a rapid increase at a much lower stretching strain (7.3%), and thicker films delay the onset of the film failure (15% at the thickness of 60 μm), suggesting a strong thickness dependence of conductance. FIG. 3B gives snapshots of 10 μm thick films at various stretching strains. Cracks appear at small strains in spin-coated films, whereas those fabricated on the liquid surface only develop cracks at significantly higher strain. Similar phenomena (FIGS. 14A and 14B) are also observed in films with other thicknesses. Cyclic stretching tests are also performed to further examine the mechanical integrity of films. Films with thickness of 10 μm fabricated on the liquid surface only exhibit less than a 1.2% change in electrical resistance after 50 cycles (N=50) with 15% stretching strain, whereas the spin coated film fails with more than 100% change in resistance after only 6 cycles (N=6), as shown in FIG. 3C. Optical images of the deformation in the film further confirm the excellent integrity, indicating the robustness of these continuous films in response to mechanical loadings, suitable for applications in flexible and stretchable structures and devices. Enhanced stretchability is also obtained in the RFID layout printed on PDMS-hexane/honey liquid substrate (FIGS. 15A and 15B). The superior, thickness-independent stretchability of the films fabricated on liquid surface is attributed to their uniform thickness. FIG. 3D illustrates the conductive mechanism of PEDOT:PSS films in response to mechanical stretch. Uniform percolation networks of electrically conductive PEDOT phase are formed in non-conductive PSS matrix. For the films formed on the liquid surface, mechanical stretching uniformly elongates these networks due to uniform thickness and homogenous distribution of PEDOT phase, resulting in thickness independent behavior. In contrast, the spin coated films experience stress concentration caused by thickness gradient, where the failure nucleates in the thinner, less PEDOT-phase rich center regions in films. Thinner films result in higher gradients of PEDOT distribution and more non-homogenous percolation networks, leading to smaller stretchability.

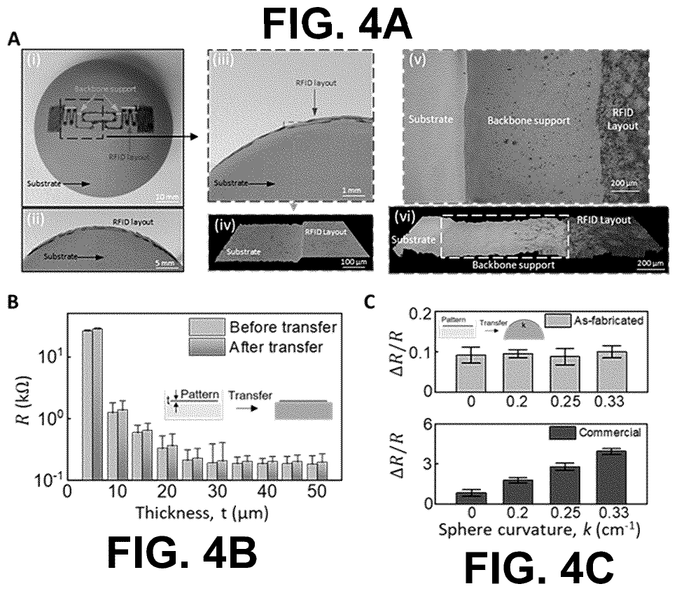

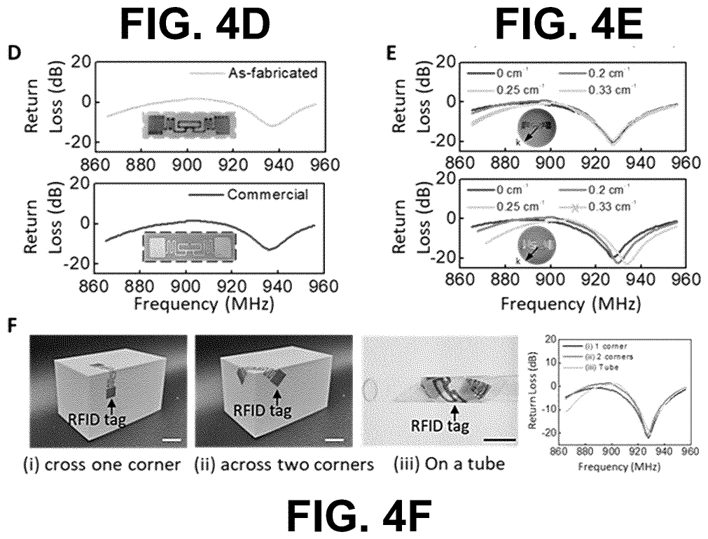

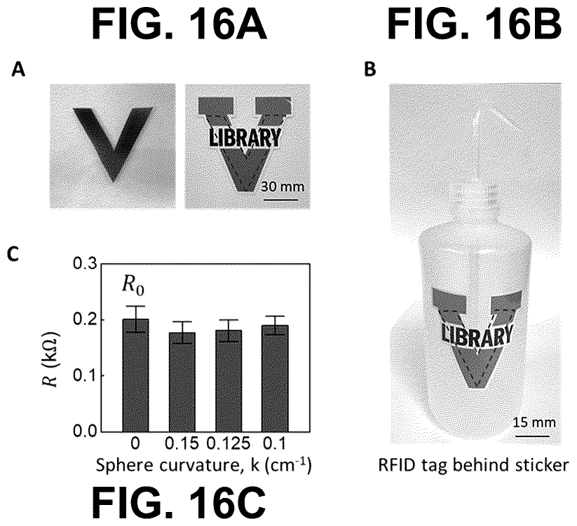

To evaluate the performance of the obtained films on curved substrates, they were transferred onto spherical substrates using the water transfer approach after fully replacing the double-layer liquid substrate with water. FIG. 4A shows the optical images of an RFID layout on a spherical substrate after transfer. PDMS backbones are used to reinforce the printed layout and prevent separation during transfer, as elaborated in the complete spreading approach (FIG. 3C). Enlarged local images and microscopy views show a seamless integration between the RFID layout and the substrate, indicating a successful transfer. Particularly, both 2D and 3D optical images at the localized area (highlighted by blue dashed box in FIG. 4A) further indicate conformal contact among the substrates, connection layers and transferred films. FIG. 4B plots the electrical resistance of RFID layouts with various fabrication thicknesses before and after transfer. The agreement across all thicknesses proves the success of the transfer without damage. When the fabricated films are transferred onto spherical substrates with different curvatures, FIG. 4C shows that their electrical resistance remains unchanged. In comparison, a commercially available RFID tag with same layout exhibits a significant increase with the increasing of the curvature, which suggests its weak mechanical flexibility and unsuitability for applications on curved substrates. The films can also be transferred onto a flexible sticker as an intermediate substrate and then mounted on a plastic bottle (FIGS. 16A-16C). When a dynamic curvature is induced by squeezing the plastic bottle, ranging from 0.15 cm⁻¹ to 0.1 cm⁻¹, the measured electrical resistance remains a negligible change. This conductance-insensitivity of RFID layout to substrate curvatures regardless of its thickness before and after transfers corroborates well with the uniform thickness of films shown in FIG. 1D and FIG. 1E and is also consistent with enhanced stretching performance observed in FIG. 3A.

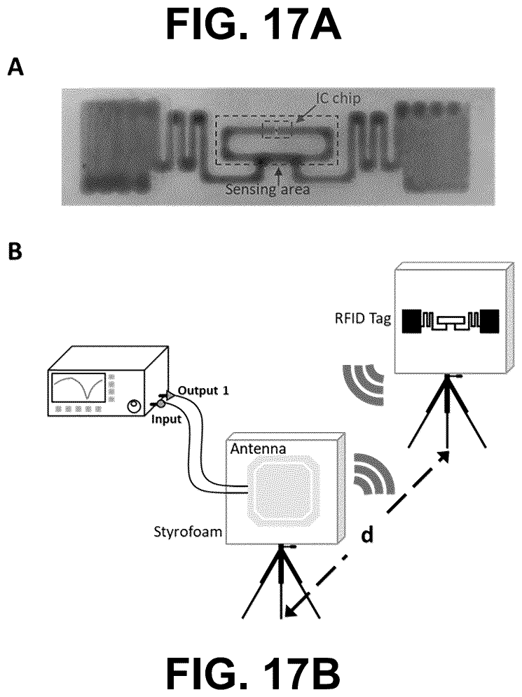

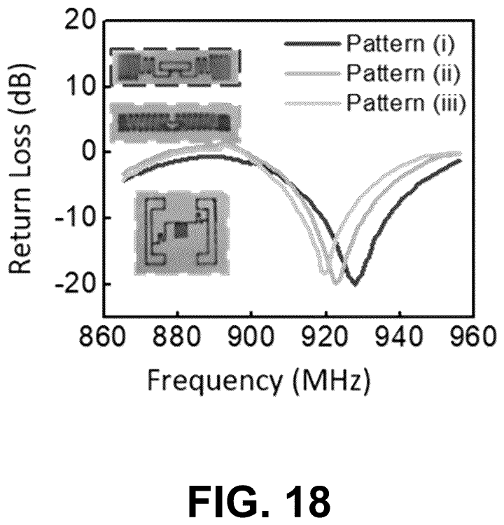

The curvature-independent electrical resistance of the fabricated RFID layouts suggests their potential for implantation of an IC chip to enable real-time signal monitoring on arbitrarily shaped objects. The RFID tag is integrated with an 865 MHz IC chip, and its equivalent electrical circuit model is given to feature a dipole antenna connected in series to a sensing unit and the chip (FIGS. 17A and 17B). The setup of RFID tag sensing system (FIG. 17B) includes an RFID reader, fabricated RFID tags, and a network analyzer (NanoVNA). FIG. 4D shows the backscattered signal, return loss (S₁₁), of the fabricated RFID tag transferred on a flat PDMS substrate, and a commercially available RFID tag for comparison. The measurement shows remarkable agreement with that of commercial standard tag. When the printed RFID tags and corresponding frequencies of the implanted IC chip change (928 MHz, 922 MHz, and 920 MHz), a corresponding frequency shift (FIG. 18) is also observed, which matches the chip frequencies. These matches confirm the design and fabrication robustness of RFID tags with different layouts on liquid surface. Unlike on a flat substrate, when mounted on spherical substrates with varying curvatures (FIG. 4E), the fabricated RFID tags of the present disclosure show negligible changes in both the magnitude and frequency of the minimum return loss, in a good consistency with the curvature-independent electrical resistance in FIG. 4D. In contrast, the commercial RFID tags show significant variations in the minimum return loss with the increasing of curvature. Particularly, when the curvature increases to 0.33 cm⁻¹, the backscattered signal cannot be detected, suggesting the dysfunctionality of the commercial standard tag. Enabled by the curvature-independent performance, the fabricated RFID tags can be conformally transferred to substrate with complex geometries, including those with (i) one, (ii) two sharp corners and (iii) tubular surfaces (FIG. 4F), where return loss data of three transferred tags are successfully recorded, is well consistent with the curvature-independent behavior.

### Application Demonstrations in Real-Time Monitoring of Food Spoilage

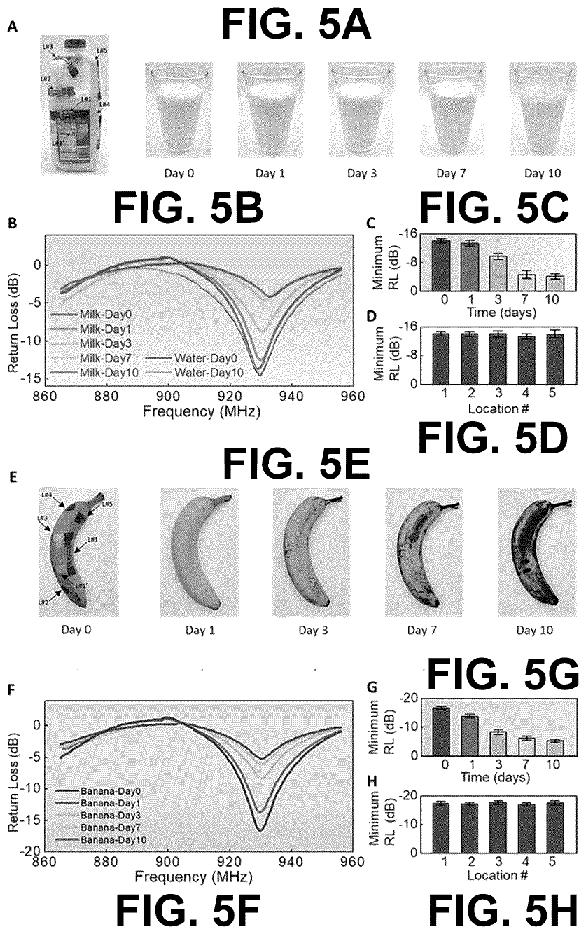

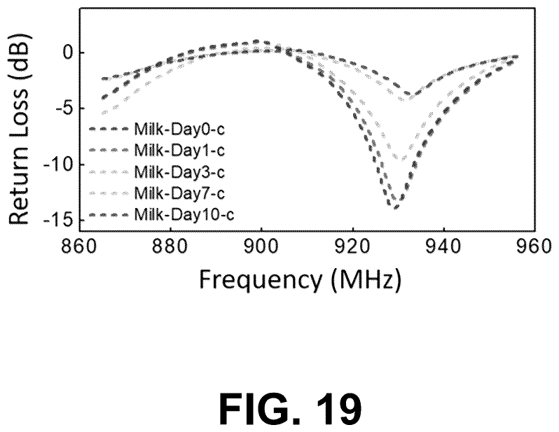

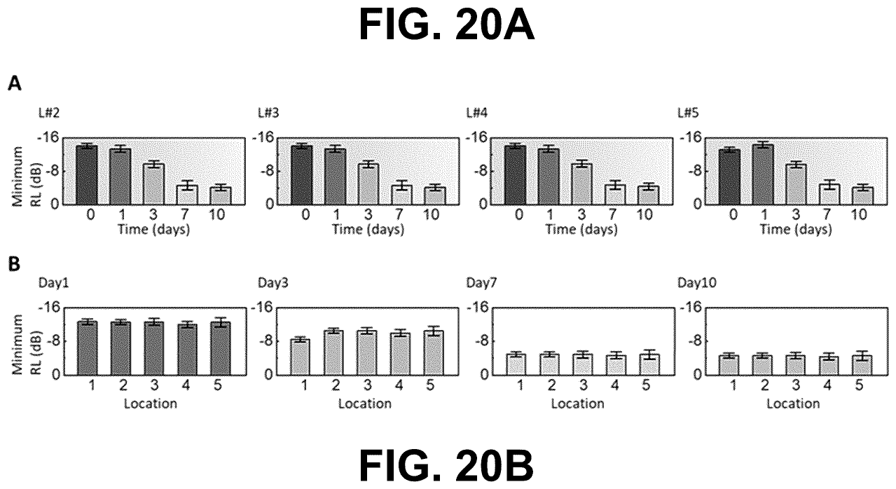

Given the wireless communication capabilities of RFID tags, a proof-of-concept application for food safety monitoring is demonstrated by mounting the fabricated super-flexible RFID tags on the “skin” surface of food. FIG. 5A shows RFID tags attached to a bottle surface of fat-free milk purchased from a local supermarket. Five identical RFID tags are positioned at various locations (labeled L #1 through L #5) that correspond to different local curvatures. A commercial RFID tag with the same layout and IC frequency is attached just below L #1 for measurement comparison, marked as L #1′. Parallel with data recording by tags, 200 ml of milk from a separate, similarly stored bottle was poured into a transparent glass cup to visually track color change. In addition, control experiment is performed with the fabricated RFID tag attached to the identical bottle filled with water under the same storage conditions. FIG. 5B shows the return loss (S₁₁) response measured from the tag at L #1 from day 0 to day 10. The responses of signals from both the fabricated RFID and commercial RFID tags (FIG. 19) are nearly identical, confirming the functionality and sensitivity of the liquid-on-surface fabricated RFID tag. Further, the minimum return loss shows a clear decrease from day 0 to day 10 for the milk sample while no change is observed for water, indicating the natural milk spoilage at room temperature. FIG. 5C summarizes the minimum return loss at L #1 over time. An obvious reduction is obtained, which echoes the visual color change of milk from white to light yellow till to a clear solid/liquid separation accompanied by strong unfriendly smells. Extended data from other positions (FIG. 20A) shows similar results and further confirms the robustness of measurement. The minimum return loss data for locations L #1 through L #5 are summarized in FIG. 5D for day 0 and FIG. 20B for subsequent days. The nearly identical minimum return loss across these five different locations shows that RFID tags perform independently of curvature or mounting position, in a great consistency with the excellent mechanical flexibility observed in the RFID layout in FIG. 4E.

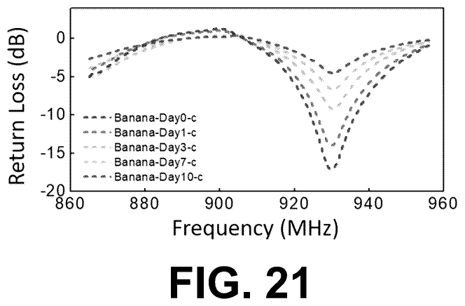

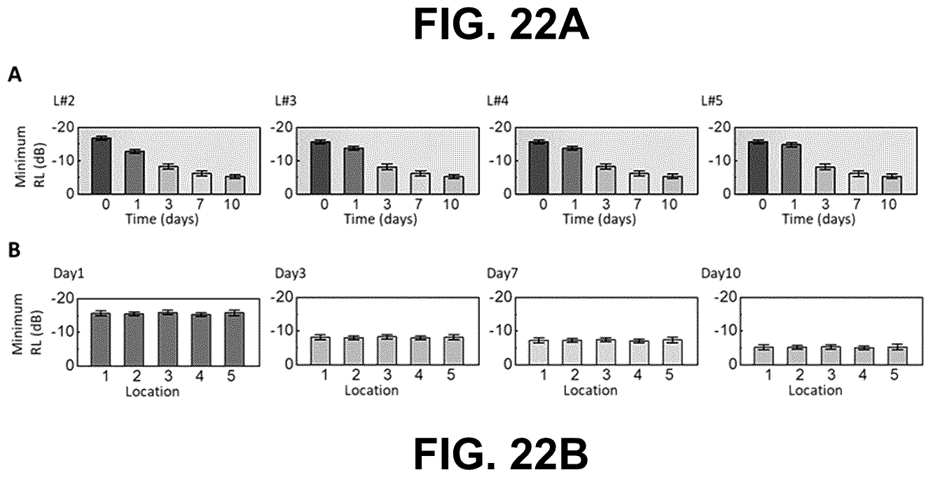

Unlike being mounted on milk bottle, the exceptional thin and flexibility of the fabricated RFID tag can also be directly attached onto the skin surface of solid food for real-time spoilage monitoring. FIG. 5E shows an optical image of the five identical liquid-on-surface fabricated RFID tags mounted on the skin of a fresh banana purchased from a local supermarket. Similar to that on milk spoilage monitoring, these five RFID tags are positioned to different locations of L #1 to L #5, while L #1′ indicates the location of a commercial RFID tag for comparison. Return loss (S₁₁) signals are recorded over swept frequency at room temperature over a 10-day period. Optical images of the banana are captured along with every data record for providing parallel visual comparison. FIG. 5F presents the data recorded at L #1. A clearly decreased minimum return loss is observed from day 0 to day 10. The results from both the fabricated and commercial RFID tags (FIG. 21) show a remarkable consistency. Similar results are also obtained at the other four positions (FIG. 22A). Bar graphs with respect to time at L #1 are plotted in FIG. 5G and reveals that the minimum return loss decreases by up to 80% by day 10 in comparison to day 0. This significant reduction aligns well with the obvious visible color change of banana skin, from green to yellow and eventually to brown, indicating the progressive spoilage of banana. Further, the measured minimum return losses across the five different tag locations remain the same, as shown in FIG. 5H for day 0 and FIG. 22B for rest days, confirming the robustness and curvature-independent performance of the RFID tags in monitoring food spoilage.

### Discussion

A low-cost and liquid-surface printing approach has been introduced for fabricating thin, uniform polymeric soft films through the controlled spreading of ink droplets on an immiscible double-layer liquid surface. Fabrication experiments on a diverse variety of continuous films and discrete structural patterns are achieved and well confirmed by the theoretical predictions with remarkable agreement. Comprehensive characterization and assessment on both structural morphology and electrical conductance on curvilinear substrates and in response to mechanical loadings proves the thickness uniformity of the fabricated films and patterns, beyond those by conventional approaches. The straightforward fabrication of RFID layouts and their robust performance across various substrates further demonstrates the fabrication robustness and reliability. Flexible RFID tags can also be fabricated with implantation of IC chips and thus demonstrate the applications in monitoring the freshness status of both liquid and solid food, offering promising opportunities in food safety industry regardless of mounting positions on food or packaging.

### Materials and Methods

### Theoretical Model and Analysis of Ink Droplet Spreading

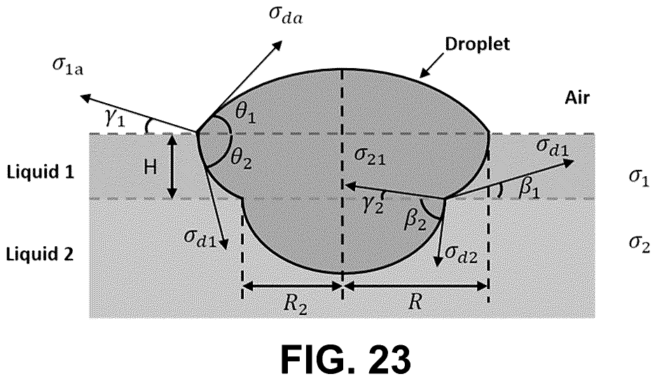

FIG. 1B and FIG. 23 illustrate the schematic of an ink droplet with radius of r and volume V (=4πr³/3) on a surface of a double-layer liquid substrate. In this system, a bottom-bulk liquid (liquid 2) is uniformly covered by a thin top-layer (liquid 1) atop with thickness H. The force equilibrium of the droplet at the interface between liquid 1 and liquid 2 will lead to:

$${σ}_{d 1} sin {β}_{1} + {σ}_{21} sin {γ}_{2} = {σ}_{d 2} sin {β}_{2} \qquad ( 1 )$$

$${σ}_{21} cos {γ}_{2} + {σ}_{d 2} cos {β}_{2} = {σ}_{d 1} cos {β}_{1} \qquad ( 2 )$$

Further, the balance of the droplet at the interface of the droplet in contact with liquid 1 among surface tension, gravity, and buoyancy will give:

$$V ρ g - {V}_{2} {ρ}_{1} g - {V}_{3} {ρ}_{2} g = 2 π R {σ}_{1 a} sin {γ}_{1} + 2 π {R}_{2} {σ}_{21} sin {γ}_{2} \qquad ( 3 )$$

Similarly, the force balance at the interface between liquid 1 and liquid 2 gives:

$$ρ {gV}_{3} - {ρ}_{2} {gV}_{3} + ρ g π {R}_{2}^{2} ( H + \frac{{V}_{1}}{2 π {R}^{2}} ) = 2 π {R}_{2} {σ}_{21} sin {γ}_{2} \qquad ( 4 )$$

where

$${V}_{1} = \frac{π}{3} {R}^{3} \frac{{( 1 - cos {θ}_{1} )}^{2} ( 2 + cos {θ}_{1} )}{{( sin {θ}_{1} )}^{3}} , {V}_{2} = {π ( \frac{R + {R}_{2}}{2} )}^{2} H , and$$

$${V}_{3} = \frac{π}{3} {R}_{2}^{3} \frac{{( 1 - cos {β}_{2} )}^{2} ( 2 + cos {β}_{2} )}{{( sin {β}_{2} )}^{3}}$$

denote the volume of the droplet exposed in air, liquid 1 and liquid 2, respectively, and V=V₁+V₂+V₃. θ₁, θ₂ and γ₁ denote contact angles of the droplet on liquid 1. β₁, β₂ and γ₂ denote contact angles of the droplet at the interface between liquid 1 and liquid 2. σ_{d1}, σ_{da}, and σ₁ₐ represent the interfacial tensions between the droplet and liquid 1, the droplet and air, and the liquid 1 and air, respectively, and σ_{d2}, σ₂₁ are the interfacial tensions between the droplet and liquid 2, and the liquid 1 and liquid 2, respectively. σ_{d}, σ₁, and σ₂ represent surface tensions of the initial droplet, liquid 1, and liquid 2, respectively. R and R₂ are the contact radius of the droplet with the liquids 1 and 2, respectively.

By solving Equations (1-4), the spreading radius R of the droplet on the surface of the top-layer liquid 1 can be written as:

$$R = \frac{2 ( {σ}_{d 2} - {σ}_{21} ) {( V - {R}^{3} )}^{- \frac{1}{3}} {R}^{2} + \frac{H}{H + r} ρ gV}{2 ( {σ}_{d 1} + {σ}_{da} )} \qquad ( 5 )$$

Note that when the thickness of liquid 1 is zero (i.e. V₂=0, H=0), the double-layer liquid substrate system reduces to a single-phase liquid 2 substrate, and the balance at the interfaces, Eqs. (3) and (4), will reduce to the classic spreading theory with Vρg−V₃ρ₂g=2πRσ₁ₐ sin γ₁ (41). When H>>r, the droplet does not contact the bottom layer (i.e. V₃=0), and the spreading dynamics reduce to that on a single liquid 1 substrate, and Eqs. (3) and (4), will reduce to Vρg−V₂ρ₁g=2πRσ₁ₐ sin γ₂.

### Preparation of Droplet Ink Solution and Double-Layer Liquid Substrate

A 1% PEDOT:PSS water solution (Sigma-Aldrich, Inc) was used to prepare two distinct inks for printing with non-spread and complete spread approaches. For Ink_1, 1.3% (by weight) PEO powders (average molar volume 600,000) were dissolved in the solution using magnetic stirrer at 250 rpm for more than 12 hr. This Ink_1 was used to generate droplets for printing films with the complete spreading control mechanism. For Ink_2, Ink_1 was further processed by adding 10% 200 proof ethanol (Sigma-Aldrich) and stirring for another 10 minutes. This Ink_2 was used to generate droplets for printing films with the non-spreading control mechanism. Silc Pig color pigments (Smooth-On) were mixed to colorize both inks for visualization.

For the double-layer liquid substrate, honey was selected as the bottom-layer bulk liquid (liquid 2) and PDMS/hexane mixture (10:1 of base polymer and cure agent by weight for PDMS, and 10% for hexane otherwise stated) was used as the top-layer liquid (liquid 1). A droplet of Ink_2 was deposited on the double-layer liquid substrate to monitor the ink's spreading. For comparison, the spreading of the same ink droplet was also conducted on the sole liquid 2 of honey substrate.

### Printing Process, Setup, and Film Characterization

TL-Pro-BM electrospinning unit was modified for printing with the non-spreading mechanism. Ink_2 was loaded into the needle syringe and extruded by the syringe pump of the spinning unit at 15 mL/hr. The selected liquid 1 and 2 were placed in a container and secured on an XY stage to form a double-layer liquid substrate. As the ink was extruded, the XY stage moved as the preprogrammed paths. Once the printing was completed, the prints remained on the stage for at least 24 hours to cure and solidify at room temperature.

For the printing with complete spreading control, a thin-thickness PDMS frame was designed to direct the ink's spreading. The frame was fabricated by fully curing a PDMS mixture with base and curing agent at 10:1 ratio and then cut into the desired patterns with OMTech 40W CO₂ Laser Cutter. The frame was carefully placed on the liquid substrate, ensuring no air bubbles were trapped. Ink_1 was deposited inside the frame to allow freely spread until it reaches the frame boundaries. After a complete spreading, the ink membrane was left on liquid surface for 24 hours to allow solidify, and the frame was subsequently removed, leaving the formed film and structures floating on the liquid surface.

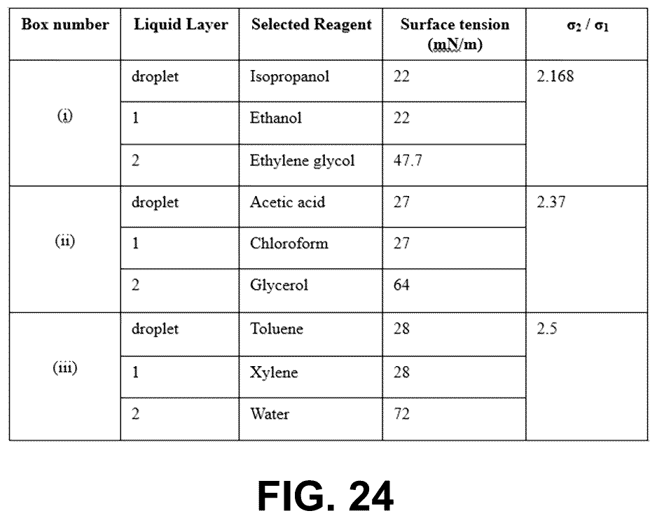

When combing both spreading and non-spreading control mechanisms to fabricate structures, the PDMS frame was first placed on the liquid substrate to define where patterns were needed by the spreading mechanism. The defined regions were printed with the spreading mechanism. Afterward, the region outside the PDMS frames were printed with non-spreading control mechanism. For printing discrete patterns, to maintain the structural integrity during transferring, PDMS solution was printed between joint regions after two regions were cured, where additional cure accelerator (10%) was added in PDMS solution to speed up the curing process. The specific reagents combination used for the printing demonstration of films and structures in FIG. 1C are summarized in FIG. 24.

After fully cured, the films were transferred to a silicon wafer substrate for surface characterization. For this transfer, the double-layer PDMS-hexane/honey liquid substrate was exchanged with deionized (DI) water. To avoid the effect of liquid flow dynamics on film's integrity during the exchange, inlet and outlet ports were designed on the bottom of the liquid container and drained and injected the liquid accordingly at the same rate. After the water exchange, the previously described pull-up transfer approach was used to transfer the films onto the wafer substrate. Because the PEDOT:PSS films are transparent, after transfer on wafer substrate, a thin layer of gold and palladium (60/40) was coated on the surface using the sputter at the pressure of 0.05 mbar, current of 30 mA, and distance of 50 mm, for 40 s, which led to a coating thickness of ~16 nm. Zygo NewView 7300 optical surface profilometer was used for surface morphology characterization.

### Mechanical and Frequency Characterization of RFID

PEDOT:PSS films were transferred on a thin PDMS films for mechanical test, like the transfer process on silicon wafer substrate in characterization. The mechanical testing was conducted on a Mark-10 ESM 303 with an M5-2 force gauge. The films were clamped uniformly at both ends along the short side on the motorized tensile test stand. The displacement was applied at 20 mm/min while electrical resistance change of the film was recorded in real-time through a digital multimeter.

For frequency characterization, the printed RFID tag was integrated with an Alien Higgs-3 Gen 2 RFID IC (Z_{c}=31−j216Ω at 865 MHz) by introducing a gap in the loop area and connecting four endpoints (FIGS. 17A and 17B). The tag was impedance-matched to a Zebra AN480 (RHCP) RFID reader with the assistance of a NanoVNA (H4-V4.3). Both the reader and the tag were fixed on polystyrene foams inside a reflection cancelling booth to reduce backscattered noise, and the devices were oriented to face each other horizontally. The NanoVNA was connected to the reader through two wires out of the booth and swept at 860-960 MHz frequency to capture the impedance response of the tag sensor as the dielectric properties of the surrounding environment changed. The recorded data consisted of real (Re) and imaginary (Im) parts and were processed using open-sourced NanoVNA-App software. The return loss (S₁₁) magnitude was then calculated using the equation: Return Loss (S₁₁) (dB)=20×log \sqrt{Re²+Im²}.

As will be apparent to those of skill in the art upon reading this disclosure, each of the individual embodiments described and illustrated herein has discrete components and features which may be readily separated from or combined with the features of any of the other several embodiments without departing from the scope or spirit of the present disclosure. Any recited method can be carried out in the order of events recited or in any other order that is logically possible.

It is also to be understood that the terminology used herein is for purposes of describing particular embodiments only and is not intended to be limiting. It is also possible in the present disclosure that steps can be executed in different sequence where this is logically possible.

It must be noted that, as used in the specification and the appended claims, the singular forms “a,” “an,” and “the” include plural referents unless the context clearly dictates otherwise.

A number of embodiments of the invention have been described. Nevertheless, it will be understood that various modifications may be made without departing from the spirit and scope of the invention. Accordingly, other embodiments are within the scope of the following claims.

Unless defined otherwise, all technical and scientific terms used herein have the same meanings as commonly understood by one of skill in the art to which the disclosed invention belongs.

Those skilled in the art will recognize or be able to ascertain using no more than routine experimentation, many equivalents to the specific embodiments of the invention described herein. Such equivalents are intended to be encompassed by the following claims.

What is claimed is:

1. A method of fabricating a film, comprising:
spreading a second liquid on a surface;
spreading a first liquid on the second liquid, wherein the first liquid has a lower density than the second liquid, wherein the first liquid has a bottom area and a top area, wherein the top area of the second liquid boarders a bottom area of the first liquid, wherein a top area of the first liquid boarders a gaseous environment, and wherein an equilibrium solubility of the second liquid in the first liquid and an equilibrium solubility of the first liquid in the second liquid is less than or equal to about 1 percent weight;
dispensing a first solution onto the first liquid to form a membrane, wherein an equilibrium solubility of the first solution in the first liquid and an equilibrium solubility of the first liquid in the first solution is less than or equal to about 1 percent weight, and wherein an equilibrium solubility of the first solution in the second liquid and an equilibrium solubility of the second liquid in the first solution is less than or equal to about 1 percent weight; and
curing the membrane to form the film.

2. The method of claim 1, further comprising transferring the film to a substrate.

3. The method of claim 1, wherein the first solution comprises one or more polymers.

4. The method of claim 3, wherein at least one of the one or more polymers is electroactive, at least one of the one or more polymers is non-electroactive, or a combination of any thereof.

5. The method of claim 1, wherein the film comprises a thickness of about 10 micrometers to about 200 micrometers, a statistical thickness variation across an area greater than or equal to about 1 square millimeter of the film is no more than about 10% of an average thickness of the film, an average surface roughness of the film is about 10 nanometers to about 1 micrometer, or a combination thereof.

6. The method of claim 1, wherein dispensing the first solution further comprises dispensing a plurality of drops of the first solution onto the first liquid based at least in part on a design to form the membrane, wherein the plurality of drops form the design.

7. The method of claim 6, wherein the design is an electrical circuit and the method further comprises disposing a radio frequency identification (RFID) chip onto the film and in connection with the electrical circuit.

8. The method of claim 1, wherein dispensing the first solution further comprises:
placing a frame on the first liquid, wherein the frame has a design; and
dispensing a plurality of drops of the first solution within the frame onto the first liquid to form the membrane, wherein the plurality of drops form the design.

9. The method of claim 1, wherein dispensing the first solution further comprises dispensing the first solution onto the first liquid based at least in part on a spreading radius of the first solution, wherein the spreading radius is based at least in part on a thickness of the first liquid, a surface tension of the first liquid, or both.

10. The method of claim 1, wherein a ratio of a surface tension of the first liquid to a surface tension of the second liquid is greater than about 0.5 and a difference between a density of the second liquid and a density of the first liquid is greater than or equal to about 0.1 g/cm³.

11. The method of claim 1, wherein the first liquid is a water-based polar liquid and the second liquid is a nonpolar liquid.

12. The method of claim 1, wherein the first liquid is a polar organic liquid and the second liquid is a nonpolar liquid.

13. The method of claim 1, wherein the first liquid comprises saline, glycerol-water, DMSO, DMF, one or more short-chain alcohols, water, or a combination of any thereof and the second liquid comprises one or more alkanes, one or more mineral oils, one or more oils, one or more fluorinated oils, one or more silicone oils, or a combination of any thereof.

14. The film fabricated according to the method of claim 1.

15. A film comprising one or more polymers, wherein the film comprises a thickness of about 10 micrometers to about 200 micrometers, a statistical thickness variation across an area greater than or equal to about 1 square millimeter of the film is no more than about 10% of an average thickness of the film, an average surface roughness of the film is about 10 nanometers to about 1 micrometer, or a combination of any thereof.

16. The film of claim 15, wherein at least one of the one or more polymers is a thermoset polymer.

17. The film of claim 15, wherein at least one of the one or more polymers is electroactive, at least one of the one or more polymers is non-electroactive, or a combination of any thereof.

18. The film of claim 15, wherein the film comprises an electrical circuit formed by the one or more polymers and a radio frequency identification (RFID) chip in connection with the electrical circuit.

19. The film of claim 15, wherein an electrical resistance of the film exhibits a change of less than about 2% after a plurality of cycles with a stretching strain of up to about 15%.

20. A substrate comprising the film of claim 15.
